(19) United States
(12) Patent Application Publication
(10) Pub. No.: US 2022/0130646 A1
(43) Pub. Date: Apr. 28, 2022

(54) PLASMA PROCESSING APPARATUS

(71) Applicant: TOKYO ELECTRON LIMITED, Tokyo (JP)

(72) Inventor: Chishio KOSHIMIZU, Miyagi (JP)

(21) Appl. No.: 17/501,889

(22) Filed: Oct. 14, 2021

(30) Foreign Application Priority Data
Oct. 22, 2020 (JP) 2020-177345

(51) Int. Cl. H01J 37/32

(52) U.S. Cl. CPC H01J 37/32568; H01J 37/32174; H01L 21/6833; H01J 2237/334; H01J 37/32091

(57) ABSTRACT

A plasma processing apparatus includes: a chamber; a first lower electrode provided inside the chamber and having a substrate placement region on which a substrate is placed; a second lower electrode disposed in a region outside the substrate placement region; a first upper electrode disposed to face the substrate placement region; a second upper electrode disposed in a region outside the first upper electrode to face the second lower electrode; and a first power supply configured to supply a first periodic signal to the first lower electrode, wherein at least one of the second lower electrode and the second upper electrode includes a recess, and the second lower electrode or the second upper electrode is located on a normal line with respect to a surface of the recess.

### CROSS-REFERENCE TO RELATED APPLICATION

This application is based upon and claims the benefit of priority from Japanese Patent Application No. 2020-177345, filed on Oct. 22, 2020, the entire contents of which are incorporated herein by reference.

### TECHNICAL FIELD

An exemplary embodiment of the present disclosure relates to a plasma processing apparatus.

### BACKGROUND

In a plasma processing apparatus disclosed in Patent Document 1 or Patent Document 2, a stepped slope is provided in the peripheral portion of an upper electrode to increase the density of plasma in the peripheral portion.

### PRIOR ART DOCUMENT

### Patent Document

Patent Document 1: Japanese Laid-Open Patent Publication No. 2004-511906
Patent Document 2: Japanese Laid-Open Patent Publication No. 2009-239014

### SUMMARY

According to one embodiment of the present disclosure, there is provided a plasma processing apparatus includes: a chamber; a first lower electrode provided inside the chamber and having a substrate placement region on which a substrate is placed; a second lower electrode disposed in a region outside the substrate placement region; a first upper electrode disposed to face the substrate placement region; a second upper electrode disposed in a region outside the first upper electrode to face the second lower electrode; and a first power supply configured to supply a first periodic signal to the first lower electrode, wherein at least one of the second lower electrode and the second upper electrode includes a recess, and the second lower electrode or the second upper electrode is located on a normal line with respect to a surface of the recess.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a view illustrating a basic structure of a plasma processing apparatus according to an exemplary embodiment.

FIG. 2 is a view illustrating a vertical cross-sectional configuration of a basic structure of a main part of the plasma processing apparatus according to the exemplary embodiment.

FIG. 3 is a graph illustrating a relationship between a vertical position Z and a potential V (a.u.).

FIG. 4 is a view illustrating a vertical cross-sectional configuration of the main part of the plasma processing apparatus according to the exemplary embodiment.

FIG. 5 is a view illustrating a vertical cross-sectional configuration of the main part of the plasma processing apparatus according to the exemplary embodiment.

FIG. 6 is a view illustrating a vertical cross-sectional configuration around a substrate in the plasma processing apparatus according to the exemplary embodiment.

FIG. 7 is a view illustrating a vertical cross-sectional configuration around a substrate in the plasma processing apparatus according to the exemplary embodiment.

FIG. 8 is a view illustrating an example of a positional relationship between an auxiliary electrode and a second electrode plate.

FIG. 9 is a view illustrating a vertical cross-sectional configuration around a substrate in the plasma processing apparatus according to the exemplary embodiment.

FIG. 10 is a view illustrating a vertical cross-sectional configuration around a substrate in the plasma processing apparatus according to the exemplary embodiment.

FIG. 11 is a view illustrating a vertical cross-sectional configuration around a substrate in the plasma processing apparatus according to the exemplary embodiment.

FIG. 12 is a view illustrating a vertical cross-sectional configuration around a substrate in the plasma processing apparatus according to the exemplary embodiment.

FIG. 13 is a view illustrating a vertical cross-sectional configuration around a substrate in the plasma processing apparatus according to the exemplary embodiment.

FIG. 14 is a view illustrating a vertical cross-sectional configuration of the main part of the plasma processing apparatus according to the exemplary embodiment.

FIG. 15 is a view illustrating an example of a positional relationship between an auxiliary electrode and a second electrode plate.

FIG. 16 is a view illustrating a connection relationship between power supplies and electrodes.

### DETAILED DESCRIPTION

Hereinafter, various exemplary embodiments will be described. In the following detailed description, numerous specific details are set forth in order to provide a thorough understanding of the present disclosure. However, it w-ill be apparent to one of ordinary skill in the art that the present disclosure may be practiced without these specific details. In other instances, well-known methods, procedures, systems, and components have not been described in detail so as not to unnecessarily obscure aspects of the various embodiments.

In an exemplary embodiment, a plasma processing apparatus is provided. The plasma processing apparatus includes a chamber, a first lower electrode, a second lower electrode, a first upper electrode, a second upper electrode, and a first power supply. The first lower electrode is provided inside the chamber and includes a substrate placement region on which a substrate is placed. The second lower electrode is disposed in a region outside the substrate placement region (hereinafter, referred to as a “substrate peripheral region”). The first upper electrode is disposed to face the substrate placement region. The second upper electrode is disposed in a region outside the first upper electrode to face the second lower electrode. The first power supply supplies a periodic signal to the first lower electrode. At least one of the second lower electrode and the second upper electrode has a recess. The second lower electrode or the second upper electrode is located on the normal line with respect to a surface of the recess.

At least one of the second lower electrode and the second upper electrode has a recess. Since electrons accelerated from the vicinity of the surface of one recess toward the other are concentrated, a plasma density in the substrate peripheral region increases. Thus, it is possible to suppress the increase of plasma density in the central portion of the substrate placement region. Therefore, it is possible to improve the in-plane uniformity of plasma.

In an exemplary embodiment, both the second lower electrode and the second upper electrode may have the recess. The recess in the second upper electrode may be located on a normal line with respect to the surface of the recess in the second lower electrode, and the recess in the second lower electrode may be located on a normal line with respect to the surface of the recess in the second upper electrode. In the second lower electrode and the second upper electrode, electrons accelerated from the vicinity of the surface of one recess toward the other recess are concentrated. In contrast, electrons accelerated from the vicinity of the surface of the other recess toward the one recess are also concentrated. Therefore, the plasma density in the substrate peripheral region increases. As a result, it is possible to suppress the increase of plasma density in the central portion of the substrate placement region. Therefore, it is possible to improve the in-plane uniformity of plasma.

In an exemplary embodiment, the plasma processing apparatus may further include a second power supply configured to supply a DC voltage to the second upper electrode. When a DC voltage is supplied to the second upper electrode, it is possible to apply a force to electrons directed to the second upper electrode, and thus it is possible to control the plasma density in the vicinity of the second upper electrode. When a repulsive force is applied to the electrons, the electrons move away from the second upper electrode, and the plasma density in the substrate peripheral region increases. As a result, it is possible to adjust a ratio of the plasma density in the central portion of the substrate placement region to the plasma density in the substrate peripheral region. Therefore, it is possible to improve the in-plane uniformity of plasma.

In an exemplary embodiment, the plasma processing apparatus may further include a third power supply configured to supply a periodic signal to the second upper electrode. When the periodic signal is applied to the second upper electrode, it is possible to improve the density of plasma generated in the vicinity of the second upper electrode. Therefore, as described above, it is possible to improve the in-plane uniformity of plasma.

In an exemplary embodiment, the plasma processing apparatus may include a first feeding line and a second feeding line. The first feeding line is configured to supply, to the first upper electrode, the periodic signal output from the third power supply. The second feeding line is configured to supply, to the second upper electrode, the periodic signal output from the third power supply. A variable impedance circuit may be provided in the first feeding line or the second feeding line.

By adjusting the impedance in the variable impedance circuit, it is possible to adjust the amount of power supplied to a target upper electrode. Accordingly, it is possible to adjust the ratio of the power supplied to the first upper electrode and the power supplied to the second upper electrode. The plasma density depends on the amount of power supplied to a target electrode. Therefore, it is possible to improve the in-plane uniformity of plasma by adjusting the ratio of the amounts of supplied power.

In an exemplary embodiment, the plasma processing apparatus may further include a fourth power supply configured to supply a DC voltage to the second lower electrode. When the DC voltage is supplied to the second lower electrode, it is possible to apply a force to electrons directed to the second lower electrode, and thus it is possible to control the plasma density in the vicinity of the second lower electrode. When a repulsive force is applied to the electrons, the electrons move away from the second lower electrode, and the plasma density in the substrate peripheral region increases. Therefore, as described above, it is possible to improve the in-plane uniformity of plasma.

In an exemplary embodiment, the plasma processing apparatus may include a third feeding line and a fourth feeding line. The third feeding line is configured to supply, to the first lower electrode, the periodic signal output from the first power supply. The fourth feeding line is configured to supply, to the second lower electrode, the periodic signal output from the first power supply. The plasma processing apparatus may include a variable impedance circuit in the third feeding line or the fourth feeding line.

By adjusting the impedance in the variable impedance circuit, it is possible to adjust the amount of power supplied to a target lower electrode. Accordingly, it is possible to adjust the ratio of the power supplied to the first lower electrode and the power supplied to the second lower electrode. The plasma density depends on the amount of power supplied to a target electrode. Therefore, it is possible to improve the in-plane uniformity of plasma by adjusting the ratio of the amounts of supplied power.

In an exemplary embodiment, the plasma processing apparatus may further include a fifth power supply configured to supply a periodic signal to the second lower electrode. When the periodic signal is applied to the second lower electrode, it is possible to improve the density of plasma generated in the vicinity of the second lower electrode. Therefore, as described above, it is possible to improve the in-plane uniformity of plasma.

In an exemplary embodiment, the plasma processing apparatus may further include a sensor configured to measure a self-bias voltage or a voltage waveform generated in the second lower electrode or the second upper electrode. The plasma processing apparatus may include a controller configured to control an impedance of the variable impedance circuit according to a measurement value measured by the sensor.

The impedance of the variable impedance circuit controls the density of plasma generated in a space above the substrate placement region (a space between the first lower electrode and the first upper electrode) and a density of plasma generated in a space above the substrate peripheral region (a space between the second lower electrode and the second upper electrode). The measurement value measured by the sensor correlates with the plasma density in the substrate peripheral region. Therefore, the controller is able to adjust the amount of power supplied to the electrode connected to the variable impedance circuit by adjusting the impedance of the variable impedance circuit according to the plasma density corresponding to the measurement value. The plasma density depends on the amount of power supplied to a target electrode. Therefore, it is possible to improve the in-plane uniformity of plasma by adjusting the ratio of the amounts of supplied power based on measurement values measured by the sensor.

In an exemplary embodiment, the plasma processing apparatus may further include a sensor configured to measure a self-bias voltage or a voltage waveform generated in the second lower electrode. The plasma processing apparatus may include a controller configured to control the output of the second power supply according to the measurement value measured by the sensor.

The measurement value measured by the sensor correlates with the amount of electrons reflected by the second lower electrode, that is, the plasma density in the substrate peripheral region. In addition, it is possible to adjust the plasma density by adjusting the output of the second power supply. Therefore, the controller is able to control the plasma density in the substrate peripheral region by adjusting the output of the second power supply according to the plasma density corresponding to the measurement value. Therefore, it is possible to improve the in-plane uniformity of plasma.

In an exemplary embodiment, the plasma processing apparatus may further include a sensor configured to measure a self-bias voltage or a voltage waveform generated at the second lower electrode. The plasma processing apparatus may include a controller configured to control the output of the fifth power supply according to the measurement value measured by the sensor.

The measurement value measured by the sensor correlates with the amount of electrons reflected by the second lower electrode, that is, the plasma density in the substrate peripheral region. The controller is able to control the plasma density in the substrate peripheral region by adjusting the output of the fifth power supply according to the plasma density corresponding to the measurement value. Therefore, as described above, it is possible to improve the in-plane uniformity of plasma.

In an exemplary embodiment, the controller may be configured to control the output of the second power supply such that a negative DC voltage greater than or equal to the magnitude of the self-bias voltage generated in the second lower electrode is generated in the second upper electrode.

When a negative DC voltage is applied to the second upper electrode, a repulsive force is applied to the electrons directed to the second upper electrode and the electrons are reflected. The reflected electrons travel to the plasma region and contribute to plasma generation. Thus, the plasma density in the substrate peripheral region increases. Therefore, as described above, it is possible to improve the in-plane uniformity of plasma.

In an exemplary embodiment, the second lower electrode and the second upper electrode may be electrically grounded. When a plasma sheath having a positive potential is formed between the second lower electrode and the second upper electrode, electrons in the vicinity of these electrodes travel toward the sheath. The electrons that have moved toward the sheath contribute to plasma generation, and thus the plasma density in the substrate peripheral region increases. Therefore, as described above, it is possible to improve the in-plane uniformity of plasma.

In an exemplary embodiment, a distance between the second upper electrode and the second lower electrode may be smaller than a distance between the first upper electrode and the first lower electrode. As a result, an electric field in the substrate peripheral region (the region between the second upper electrode and the second lower electrode) can be strengthened, and the plasma density in this region can be increased. Therefore, as described above, it is possible to improve the in-plane uniformity of plasma.

In an exemplary embodiment, the plasma processing apparatus may include a conductive edge ring between the substrate placement region in which a substrate is placed and the second lower electrode. The edge ring is able to adjust the electric field in the peripheral portion of the substrate placement region. Therefore, it is possible to improve the uniformity of plasma processing.

In an exemplary embodiment, the second upper electrode and the second lower electrode may be disposed such that a normal with respect to the bottom surface of the recess is inclined relative to a normal line with respect to the substrate placement region. By changing the distance between the second upper electrode and the second lower electrode and/or the inclined angle, it is possible to change the intensity and shape of the plasma in the substrate peripheral region. Since the degree of freedom in designing the in-plane distribution of plasma density is improved, it is possible to improve the in-plane uniformity of plasma.

In an exemplary embodiment, the second upper electrode may be configured with an inner wall of the chamber or a deposition shield provided along the inner wall of the chamber. In this case, since the second upper electrode also serves as the inner wall of the chamber or the deposition shield, the number of components can be reduced while achieving the above-mentioned effects.

Hereinafter, various exemplary embodiments will be described in detail with reference to the drawings. In each of the drawings, the same or corresponding parts will be denoted by the same reference numerals, and a redundant description thereof will be omitted.

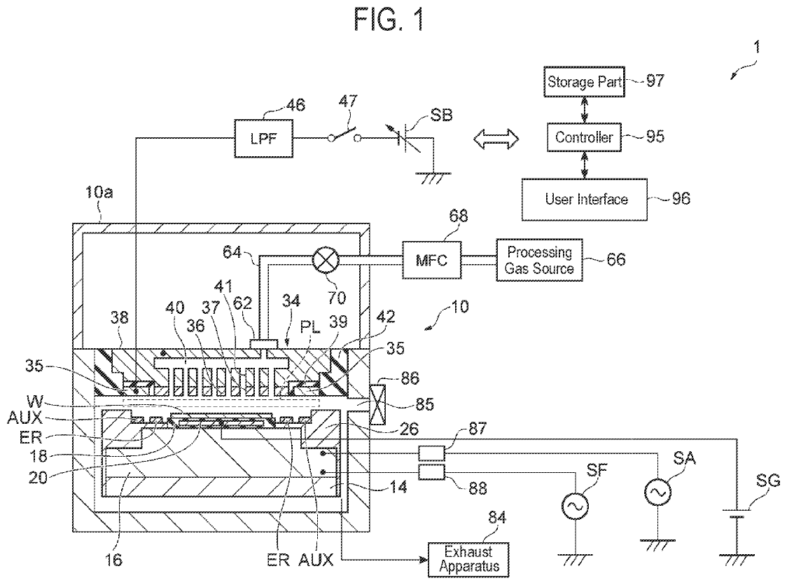

FIG. 1 is a view illustrating a basic structure of a plasma processing apparatus 1 according to an exemplary embodiment. The plasma processing apparatus 1 in the present embodiment is, for example, a capacitively coupled parallel plate plasma etching apparatus. The plasma processing apparatus 1 includes, for example, a substantially cylindrical chamber 10 formed of aluminum the surface of which has been anodized. The chamber 10 is grounded for security.

In the bottom portion of the chamber 10, a columnar support base 14 is disposed via an insulating plate formed of ceramic or the like. A stage 16 made of, for example, aluminum or the like, is provided on the support base 14. The stage 16 functions as a lower electrode (the first lower electrode).

The stage 16 has a substrate placement region on which a substrate is placed. An electrostatic chuck 18 is provided on the top surface of the stage 16 to attract and hold a semiconductor wafer W, which is an example of the substrate, by an electrostatic force. The electrostatic chuck 18 has a structure in which an electrode 20 formed of a conductive film is sandwiched between a pair of insulating layers or insulating sheets. A DC power supply SG is electrically connected to the electrode 20. The semiconductor wafer W is placed on the top surface of the electrostatic chuck 18, and is attracted and held by the electrostatic chuck 18 by an electrostatic force generated by a DC voltage supplied from the DC power supply SG. The top surface of the electrostatic chuck 18 on which the semiconductor wafer W is placed is an example of the substrate placement region of the stage 16.

An edge ring ER is provided on the top surface of the stage 16. The edge ring ER is provided to surround the substrate placement region. The edge ring ER has an annular shape, and is disposed such that the vertical central axis of the electrostatic chuck 18 and the vertical central axis of the edge ring ER coincide with each other. The edge ring ER is made of a conductive material such as silicon. The edge ring ER may be placed on the electrostatic chuck 18. When viewed from above, the edge ring ER is provided between the substrate placement region and an auxiliary electrode AUX. The edge ring ER may adjust an electric field such that active species travels along the vertical direction (the direction perpendicular to a substrate surface) in the peripheral portion of the substrate placement region. The edge ring ER improves the uniformity in plasma processing such as etching. An insulating member 26 including, for example, a cylindrical inner wall member made of quartz is provided on the side surfaces of the stage 16 and the support base 14. The insulating member 26 may include a plurality of components, and conductive wires or the like may be arranged inside the insulating member 26.

The auxiliary electrode AUX is an annular member provided on the outer peripheral side of the edge ring ER, and is disposed such that the vertical central axis of the electrostatic chuck 18 and the vertical central axis of the auxiliary electrode AUX coincide with each other. That is, the auxiliary electrode AUX is disposed concentrically with the edge ring ER, and is disposed in a region outside the substrate placement region (the substrate peripheral region). The auxiliary electrode AUX is made of a conductive material such as silicon and is placed on the insulating member 26.

For example, an annular coolant chamber is formed inside the stage 16. A coolant having a predetermined temperature, such as cooling water, is circulated and supplied to the coolant chamber from an externally provided chiller unit via a pipe. The temperatures of the stage 16 and the electrostatic chuck 18 are controlled by the coolant circulated in the coolant chamber, and the semiconductor wafer W on the electrostatic chuck 18 is controlled to a predetermined temperature.

Further, a heat transfer gas, such as a He gas from a heat transfer gas supply mechanism (not illustrated), is supplied to a space between the top surface of the electrostatic chuck 18 and the rear surface of the semiconductor wafer W via the pipe inside the stage 16.

Above the stage 16 that functions as a lower electrode, an upper electrode 34 is provided to face the stage 16. The space between the upper electrode 34 and the stage 16 becomes a plasma generation space, and plasma PL is generated in this space.

The upper electrode 34 is supported in the upper portion of the chamber 10 via an insulative shield member 42. The insulative shielding member 42 may be a cylindrical insulating member provided with a stepped portion for support on the inner surface thereof. The upper electrode 34 includes a first electrode plate 36 (the first upper electrode), a second electrode plate 35 (the second upper electrode), and an electrode support 38. The first electrode plate 36 forms a surface facing the stage 16 and includes a large number of ejection holes 37. The first electrode plate 36 and the second electrode plate 35 are preferably made of a low-resistance conductor or semiconductor having low Joule heat, and are preferably formed of, for example, silicon or SIC. The second electrode plate 35 has an annular shape, and is provided concentrically around the first electrode plate 36 to surround the first electrode plate 36. The first electrode plate 36 is provided at a position above the edge ring ER and the electrostatic chuck 18. The second electrode plate 35 is provided at a position above the auxiliary electrode AUX. The second electrode plate 35 is insulated from the first electrode plate 36 by an insulative member 39. When radio-frequency power is applied to the upper electrode 34, the insulative member 39 may be formed thin such that a radio-frequency current can flow therethrough. The illustrated first electrode plate 36 and second electrode plate 35 are examples, and various modifications are possible.

The electrode support 38 detachably supports the first electrode plate 36 and the second electrode plate 35. The electrode support 38 has a water-cooled structure formed of a conductive material such as aluminum the surface of which has been anodized. Inside the electrode support 38, a gas diffusion chamber 40 is provided. From the gas diffusion chamber 40, a large number of gas flow holes 41 communicating with the ejection holes 37 extend downward.

The electrode support 38 includes a gas inlet 36c formed therein to guide a processing gas to the gas diffusion chamber 40, and a gas supply pipe 64 is connected to the gas inlet 62.

A processing gas source 66 is connected to the gas supply pipe 64 via a valve 70 and a mass flow controller (MFC) 68. When an etching process is performed on the semiconductor wafer W, a processing gas for etching is supplied to the gas diffusion chamber 40 from the processing gas source 66 through the gas supply pipe 64. The processing gas supplied into the gas diffusion chamber 40 diffuses in the gas diffusion chamber 40 and is ejected into the plasma processing space in the form of a shower through the respective gas flow holes 41 and ejection holes 37. That is, the upper electrode 34 also functions as a shower head for supplying the processing gas into the plasma processing space.

A power supply SB is electrically connected to the second electrode plate 35 via a low-pass filter (LPF) 46 and a switch 47. The power supply SB of the present example is a variable DC power supply. The power supply SB outputs a negative DC voltage having a magnitude (an absolute value) instructed by the controller 95. The switch 47 controls the supply and cutoff of the negative DC voltage from the power supply SB to the second electrode plate 35.

The controller 95 may be configured with a central processing unit (CPU) of a computer, and is able to execute a processing process stored in a storage part 97. When a user interface 96 is an input device such as a keyboard or a button, commands may be input from the input device to the controller 95. When the user interface 96 is an output device such as a display, processing results from the controller 95 may be displayed.

A cylindrical ground conductor 10a is provided on the sidewall of the chamber 10 above the height position of the upper electrode 34. The ground conductor 10a includes a ceiling wall thereon.

A power supply SA is electrically connected to the stage 16, which functions as a lower electrode, via a first matcher 87. The power supply SA of this example is a radio-frequency power supply that generates a periodic signal. In this specification, the periodic signal is an electric signal having a voltage waveform and a current waveform that change periodically, and refers to an electric signal output by a radio-frequency power supply or a pulse power supply. An electrical signal obtained by amplifying a periodic arbitrary signal with an amplifier is also included. A power supply SF is electrically connected to the stage 16 via a second matcher 88. The power supply SF of this example is also a radio-frequency power supply that generates a periodic signal, but the frequency of the power is different from that of the power supply SA. The power supply SA is a power supply for plasma generation, and outputs a first radio-frequency power having a frequency of 13 MHz or higher, for example, 40 MHz. The power supply SF is a power supply for ion attraction, has a frequency lower than the radio-frequency power of the power supply SA, and outputs a second radio-frequency power of 27 MHz or less, for example 2 MHz. Instead of the power supply SF, a pulse power supply configured to periodically output a pulsed negative-polarity voltage may be used as the power supply that generates a periodic signal. The pulse power supply may be a DC pulse power supply that periodically outputs a negative polarity DC voltage or an impulse power supply that instantaneously and periodically outputs a negative polarity voltage.

The first matcher 87 is configured to match the impedance of the power supply SA and the load impedance such that the impedance of the power supply SA and the load impedance apparently coincide with each other when plasma is generated in the chamber 10. Similarly, the second matcher 88 is configured to match the impedance of the power supply SF and the load impedance such that the impedance of the power supply SF and the load impedance apparently coincide with each other when plasma is generated in the chamber 10.

An exhaust port is provided in the bottom portion of the chamber 10, and an exhaust apparatus 84 is connected via an exhaust pipe. The exhaust apparatus 84 includes a vacuum pump such as a turbo molecular pump, and is capable of depressurizing the interior of the chamber 10 to a desired degree of vacuum. An opening 85 for carry-in/out of the semiconductor wafer W is provided in the sidewall of the chamber 10, and the opening 85 is configured to be opened/closed by a gate valve 86.

A deposition shield configured to prevent etching by-products (deposits) from adhering to the inner wall of the chamber 10 is provided on the inner wall of the chamber 10 along the inner wall of the chamber 10. The deposition shield is also provided on the outer periphery of the insulating member 26. An exhaust plate (not illustrated) is provided between the deposition shield on the chamber wall side and the deposition shield on the insulating member 26 side in the bottom portion of the chamber 10. As the deposition shield and the exhaust plate, for example, an aluminum material coated with ceramic such as Y₂O₃ may be preferably used. The deposition shield may be electrically connected to a ground potential (a ground) to prevent abnormal discharge in the chamber 10.

Each component of the plasma processing apparatus 1 is controlled by the controller 95. A user interface 96 including a keyboard for a process manager to input commands for managing the plasma processing apparatus 1, a display configured to visualize and display the operating status of the plasma processing apparatus 1, or the like is connected to the controller 95.

Programs include a control program or the like for implementing various processes executed by the plasma processing apparatus 1 under the control of the controller 95 or a program that causes each component of the plasma processing apparatus 1 to execute a process according to processing conditions. These programs and recipes indicating processing conditions are stored in the storage part 97, and the storage part 97 is connected to the controller 95. The storage part 97 is, for example, a hard disk or a semiconductor memory. The storage part 97 may be a non-transitory portable storage medium that can be read by a computer. In this case, the controller 95 acquires a control program or the like stored in the storage medium via a device that reads data from the storage medium. The storage medium is, for example, a CD-ROM, a DVD, or the like.

The controller 95 controls each part of the plasma processing apparatus 1 by reading an arbitrary recipe from the storage part 97 and executing the recipe in response to an instruction from the user via the user interface 96 so that a predetermined plasma process is performed on the semiconductor wafer W. The plasma processing apparatus 1 in the present embodiment includes the controller 95, the user interface 96, and the storage part 97.

When an etching process is performed on the semiconductor wafer W in the plasma processing apparatus 1 configured as described above, the gate valve 86 is first controlled to be in the open state, and the semiconductor wafer W to be etched is carried into the chamber 10 through the opening 85. Next, the semiconductor wafer W is placed on the electrostatic chuck 18. Then, a predetermined DC voltage is applied to the electrostatic chuck 18 from the DC power supply SG, and the semiconductor wafer W is attracted and held on the top surface of the electrostatic chuck 18.

Then, a processing gas for etching or the like is supplied from the processing gas source 66 to the gas diffusion chamber 40 at a predetermined flow rate, and the processing gas is supplied into the chamber 10 through the gas flow holes 41 and the ejection holes 37. In addition, the interior of the chamber 10 is evacuated by the exhaust apparatus 84, and the pressure in the chamber 10 is controlled to a predetermined pressure. In the state in which the processing gas is supplied into the chamber 10, radio-frequency power for plasma generation is applied to the stage 16 from the power supply SA, and radio-frequency power for ion attraction is applied to the stage 16 from the power supply SF. In addition, a negative DC voltage (potential) of a predetermined magnitude is applied to the second electrode plate 35 from the power supply SB.

The processing gas ejected from the ejection holes 37 in the upper electrode 34 are turned into plasma in the space between the upper electrode 34 and the stage 16 by the radio-frequency power applied to the stage 16. The semiconductor wafer W is etched by the radicals and ions generated by this plasma. The above-described process is executed according to an instruction from the controller 95.

Next, the potential of the auxiliary electrode will be described.

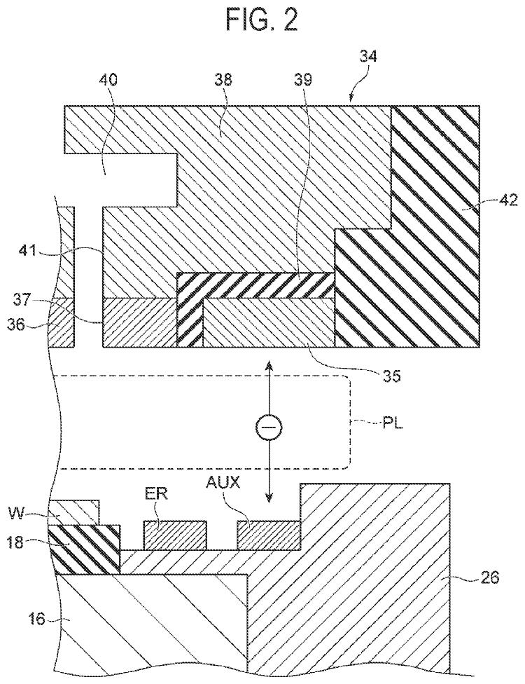

FIG. 2 is a view illustrating a vertical cross-sectional configuration of a basic structure of a main part of the plasma processing apparatus illustrated in FIG. 1.

The edge ring ER and the auxiliary electrode AUX are placed on the insulating member 26 including a plurality of parts such as a quartz ring. The portion of the insulating member 26 on which the edge ring ER is placed is formed thin so that radio-frequency currents from the power supply SA and the power supply SF flow to the edge ring ER via the stage 16. The auxiliary electrode AUX is coupled to the edge ring ER via a parasitic capacitance C. When the portion of the insulating member 26 on which the auxiliary electrode AUX is placed is formed thin, so that radio-frequency currents from the power supply SA and the power supply SF flow to the auxiliary electrode AUX via the stage 16. Therefore, the auxiliary electrode AUX has a potential that fluctuates periodically. Since a self-bias voltage which is a negative DC voltage is generated in the auxiliary electrode AUX, the potential of the auxiliary electrode AUX fluctuates periodically with reference to a self-bias voltage Vdc.

A DC voltage of −V2 is applied to the second electrode plate 35 facing the auxiliary electrode AUX by the power supply SB. Electrons having a negative charge (−) move according to an electric field between the auxiliary electrode AUX and the plasma and an electric field between the plasma and the second electrode plate 35.

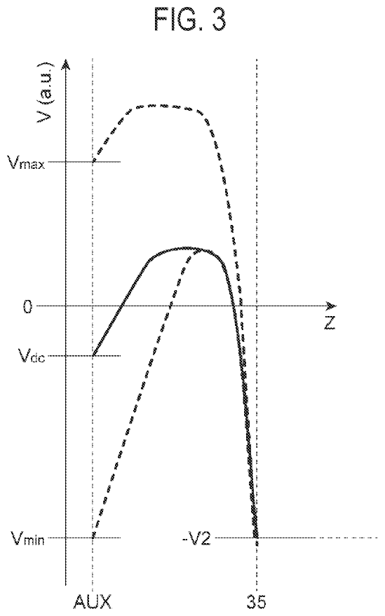

FIG. 3 is a graph illustrating a relationship between a vertical position Z and a potential V (a.u.), and schematically illustrates a potential distribution between the auxiliary electrode AUX and the second electrode plate 35. The vertically upward direction of the plasma processing apparatus is the positive direction in the Z-axis direction, and each potential indicates a voltage based on the ground potential (V=0). The magnitude (absolute value) of the negative voltage (−V2) applied to the second electrode plate 35 may be set to be equal to the magnitude (absolute value) of a self-bias voltage Vdc which is a negative voltage generated in the auxiliary electrode AUX.

The potential of the auxiliary electrode AUX periodically fluctuates between a maximum value Vmax and a minimum value Vmin with reference to the self-bias voltage Vdc. When the potential of the auxiliary electrode AUX is the self-bias voltage Vdc, the potential distribution illustrated by the solid line is obtained. When the potential of the auxiliary electrode AUX has the maximum value Vmax or the minimum value Vmin, the potential distribution illustrated by the dotted line is obtained. The sheath thickness between the auxiliary electrode AUX and the plasma fluctuates according to the fluctuation of the potential of the auxiliary electrode AUX.

The electrons, which exist in the plasma in the vicinity of the auxiliary electrode AUX when the sheath is thin, receive a force due to a high electric field applied perpendicularly to the surface of the auxiliary electrode AUX when the sheath becomes thick. The electrons receiving this force are accelerated toward the second electrode plate 35 facing the auxiliary electrode AUX (toward the plasma). Similarly, secondary electrons generated by the collision of ions with the auxiliary electrode AUX also receive a force by a sheath electric field between the auxiliary electrode AUX and the plasma. The electrons receiving this force are accelerated toward the second electrode plate 35 (toward the plasma). Some of these accelerated electrons collide with particles in the plasma and contribute to the improvement of plasma density. The remaining accelerated electrons that did not collide with the particles in the plasma travel toward the second electrode plate 35.

The accelerated electrons traveling toward the second electrode plate 35 receive a repulsive force due to the sheath electric field between the second electrode plate 35 and the plasma. The strength of the sheath electric field is proportional to the difference between a plasma potential and a wall potential. Therefore, when the difference between the plasma potential and the potential (wall potential) of the second electrode plate 35 is smaller than the difference between the plasma potential and the potential (wall potential) of the auxiliary electrode AUX (an entry condition), the accelerated electrons will enter the second electrode plate 35.

In addition, when the difference between the plasma potential and the potential (wall potential) of the second electrode plate 35 is greater than the difference between the plasma potential and the potential (wall potential) of the auxiliary electrode AUX (a reflection condition), the accelerated electrons receive a repulsive force in the direction opposite to the direction toward the second electrode plate 35. That is, when this reflection condition is satisfied, the accelerated electrons receive a repulsive force greater than the force received by the sheath electric field between the plasma potential and the auxiliary electrode AUX, and are accelerated toward the plasma (toward the auxiliary electrode AUX). Some of the accelerated electrons collide with the particles in the plasma and contribute to the improvement of plasma density.

Therefore, the potential of the second electrode plate 35 is set such that the difference between the plasma potential and the potential (wall potential) of the second electrode plate 35 is greater than the difference between the plasma potential and the potential (wall potential) of the auxiliary electrode AUX. As a result, the electrons that did not collide with the particles in the plasma and did not contribute to the improvement of the plasma density can be returned to the plasma again, and can contribute to the improvement of the plasma density. The potential of the auxiliary electrode AUX periodically fluctuates between the maximum value Vmax and the minimum value Vmin with reference to the self-bias voltage Vdc. In addition, the plasma potential is higher than the potential of the auxiliary electrode AUX. Therefore, even if the potential of the second electrode plate 35 is the ground potential (V=0), during the period in which the potential of the auxiliary electrode AUX is positive, the difference between the plasma potential and the potential (wall potential) of the second electrode plate 35 becomes greater than the difference between the plasma potential and the potential (wall potential) of the auxiliary electrode AUX.

However, since the period in which the potential of the auxiliary electrode AUX is negative is longer, most of the accelerated electrons that did not collide with the particles in the plasma enter the second electrode plate 35 and hardly contribute to the improvement of plasma density.

Therefore, in the present embodiment, a negative voltage (−V2) having a magnitude (absolute value) equal to or greater than the magnitude (absolute value) of the negative self-bias voltage Vdc generated in the auxiliary electrode AUX is applied to the second electrode plate 35. By setting the magnitude (absolute value) of the negative DC voltage (−V2) to be equal to or greater than the magnitude (absolute value) of the negative self-bias voltage Vdc generated in the auxiliary electrode AUX, at least half of the accelerated electrons, which have not collided with the particles in the plasma, can be returned to the plasma again. As a result, plasma can be efficiently generated even in the peripheral portion of the substrate in which the plasma density is low. Therefore, it is possible to improve the uniformity of plasma.

As described above, the plasma processing apparatus of this example includes a power supply SB (the second power supply) configured to supply a DC voltage (−V2) to the second electrode plate 35. When a DC voltage is supplied to the second electrode plate 35, a force can be applied to the electrons directed to the second electrode plate 35. Thus, it is possible to control the plasma density in the vicinity of the second electrode plate 35. When a repulsive force is applied to the electrons, the electrons move away from the second electrode plate 35, and the plasma density in the substrate peripheral region increases. As a result, it is possible to adjust the ratio of the plasma density in the central portion of the substrate placement region and the plasma density in the substrate peripheral region. Therefore, it is possible to improve the in-plane uniformity of plasma.

The controller 95 controls the output of the power supply (the second power supply) such that a negative DC voltage (−V2) having a magnitude equal to or greater than the magnitude of the self-bias voltage Vdc generated in the auxiliary electrode AUX is generated in the second electrode plate 35. Here, the self-bias voltage Vdc is negative. When a negative DC voltage (−V2) is applied to the second electrode plate 35, a repulsive force is applied to the electrons directed to the second electrode plate 35 and the electrons are reflected. The reflected electrons travel to the plasma region and contribute to plasma generation. Thus, the plasma density in the substrate peripheral region increases. Therefore, it is possible to improve the in-plane uniformity of plasma. This control is also applicable to all other embodiments.

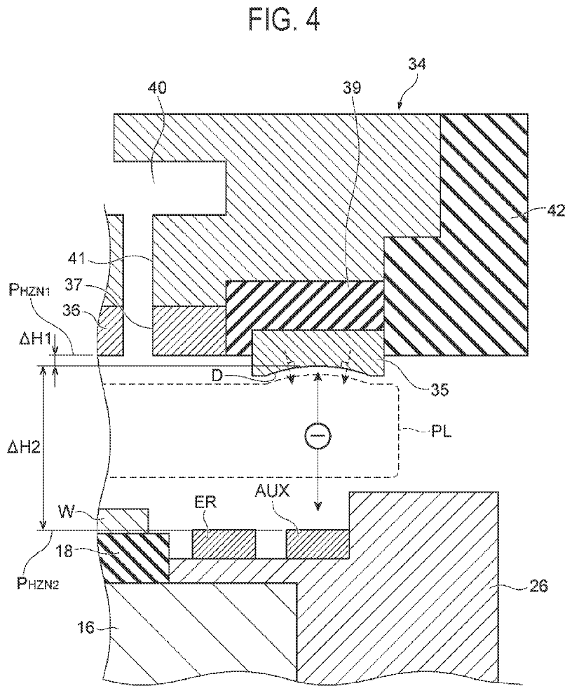

Next, the shape of each electrode will be described in detail with reference to FIGS. 4 to 7.

FIG. 4 is a view illustrating a vertical cross-sectional configuration of a main part of the plasma processing apparatus.

In the basic structure of the plasma processing apparatus illustrated in FIG. 2, the surfaces of the second electrode plate 35 and the auxiliary electrode AUX are flat surfaces. However, in this example, the surface of at least one of the second electrode plate 35 and the auxiliary electrode AUX has a recess D. The other electrode part may be located on a normal line with respect to the surface of one recess D. In the plasma processing apparatus illustrated in FIG. 4, the bottom surface of the second electrode plate 35 is machined into a concave surface to form an annular recess D. The annular recess D surrounds the vertical central axis of the substrate peripheral region. The surface of the recess D is a continuous curved surface such as a paraboloid. The top surface of the auxiliary electrode AUX illustrated as an example is a flat surface that is the same plane as or parallel to the substrate placement region. The normal line with respect to the surface of the recess D in the second electrode plate 35 intersects the top surface of the auxiliary electrode AUX. That is, the auxiliary electrode AUX is located on the normal line with respect to the surface of the recess D in the second electrode plate 35.

In this example, since the bottom surface of the second electrode plate 35 has the recess D, the density of intersections between a plurality of normal lines with respect to the bottom surface of the second electrode plate 35 and the top surface of the auxiliary electrode AUX increases in the central region in the ring width direction compared with that in the case of FIG. 2. The central region in the ring width direction is a region located between the outer peripheral region and the inner peripheral region of the annular auxiliary electrode AUX. Therefore, secondary electrons generated from the second electrode plate 35 and electrons accelerated by the sheath electric field between the second electrode plate 35 and the plasma are accelerated toward the central region of the auxiliary electrode AUX in the ring width direction. Since the accelerated electrons are concentrated toward the central region of the auxiliary electrode AUX in the ring width direction, it is possible to suppress the increase of plasma density on the substrate placement region side, and thus it is possible to improve the in-plane uniformity of plasma.

The distance (the shortest distance ΔH2) between the center position of the bottom surface of the second electrode plate 35 in the width direction (radial direction) and the horizontal plane P_{HZN2} including the top surface of the lower auxiliary electrode AUX may be set to be smaller than that in the case of FIG. 2. In other words, the bottom surface of the second electrode plate 35 is located below the bottom surface of the first electrode plate 36. The center position of the bottom surface of the second electrode plate 35 in the width direction (radial direction) and the horizontal plane P_{HZN1} including the bottom surface of the first electrode plate 36 are spaced apart from each other by a distance (the shortest distance ΔH1). As a result, it is possible to make the electric field in the peripheral edge portion (the second electrode plate 35) stronger than that in the central portion (the first electrode plate 36). Therefore, it is possible to increase the plasma density in the peripheral edge portion, and thus it is possible to improve the uniformity of plasma.

As described above, the distance ΔH2 between the second electrode plate 35 (the second lower electrode) and the auxiliary electrode AUX (the second lower electrode) is smaller than the distance between the first electrode plate 36 and the stage 16 (ΔH1+ΔH2+the vertical distance from the surface of the auxiliary electrode AUX to the surface of the stage 16). In addition, the relation of ΔH2<ΔH1+ΔH2 is established. As a result, it is possible to strengthen the electric field in the substrate peripheral region (the region between the second electrode plate 35 and the auxiliary electrode AUX), and thus it is possible to increase the plasma density in this region. As in the example of FIG. 4, since the height of the second electrode plate 35 is lowered, it is possible to increase the plasma density in the lower region of the second electrode plate 35. Therefore, it is possible to improve the in-plane uniformity of plasma. This structure is also be applicable to all other embodiments.

The vertical cross-sectional shape of the recess D does not have to be a curved shape.

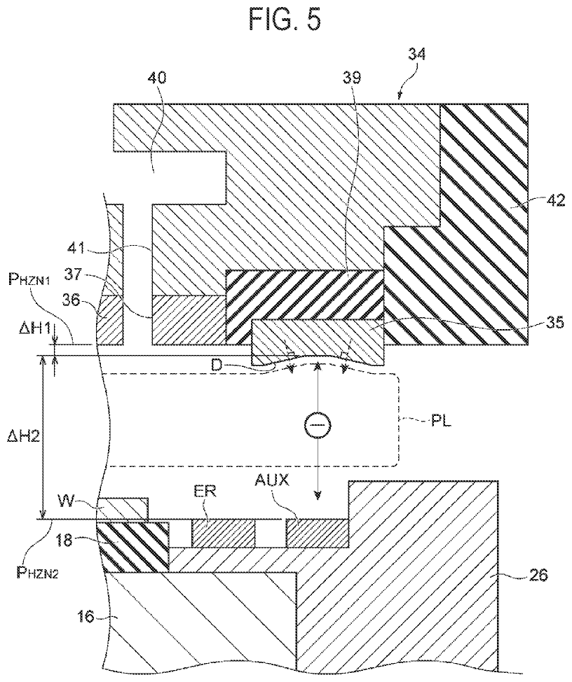

FIG. 5 is a view illustrating a vertical cross-sectional configuration of a main part of the plasma processing apparatus, which is different from the apparatus of FIG. 4 only in the shape of the recess D. That is, in this example, the bottom surface of the second electrode plate 35 is machined into a shape obtained by removing the trapezoid in the vertical cross section passing through the vertical central axis of the substrate placement region to form the recess D. The recess D may also be formed by a tapered surface. The tapered surface is substantially flat within a micro-region. The intersection line between the tapered surface and the vertical cross section passing through the vertical central axis of the substrate placement region is a line segment, rather than having a curved shape. Since the outer tapered surface surrounds the vertical central axis of the substrate placement region, the outer tapered surface may have the shape of the side surface of a truncated cone that is tapered vertically upward. Similarly, since the inner tapered surface surrounds the vertical central axis of the substrate placement region, the inner tapered surface may have the shape of the side surface of a truncated cone that is tapered vertically downward.

The inclined angle of the tapered surface may be set to an angle at which a normal line on the tapered surface intersects the auxiliary electrode AUX. Therefore, the auxiliary electrode AUX is located on a normal line with respect to the surface (the tapered surface) of the recess D in the second electrode plate 35. More preferably, the inclined angle of the tapered surface is an angle at which the intersections between a plurality of normal lines with respect to the bottom surface of the second electrode plate 35 and the top surface of the auxiliary electrode AUX exist in the central region in the ring width direction. The central region in the ring width direction is a region located between the outer peripheral region and the inner peripheral region of the annular auxiliary electrode AUX. Since the intersections between the plurality of normal lines with respect to the tapered surface of the second electrode plate 35 and the auxiliary electrode AUX are concentrated in the central region in the ring width direction, the same effect as in the case of FIG. 4 can be obtained.

The recess D may be provided in the auxiliary electrode AUX.

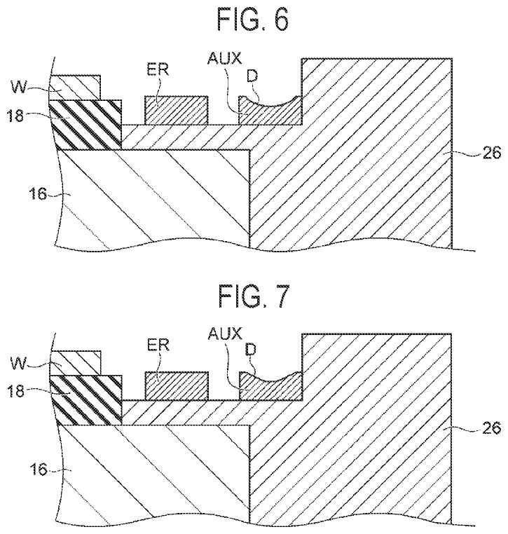

FIG. 6 is a view illustrating a vertical cross-sectional configuration around a substrate in the plasma processing apparatus. This example illustrates a configuration in which the auxiliary electrode AUX has a recess D. The shape of the recess D is the same as that of the recess D illustrated in FIG. 4, except that the former is upside down. The surface of the recess D is a continuous curved surface such as a paraboloid. A normal line with respect to the surface of the recess D in the auxiliary electrode AUX intersects the bottom surface of the second electrode plate 35. That is, the second electrode plate 35 is located on a normal line with respect to the surface of the recess D in the auxiliary electrode AUX. Even if the recess D is provided in the auxiliary electrode AUX, electrons are concentrated toward the inside of the central region of the second electrode plate 35 in the ring width direction. Therefore, it is possible to further suppress the increase of plasma density in the central portion of the substrate placement region, and thus it is possible to improve the in-plane uniformity of plasma.

FIG. 7 is a view illustrating a vertical cross-sectional configuration around a substrate in the plasma processing apparatus.

This example also illustrates a configuration in which the auxiliary electrode AUX has a recess D. The shape of the recess D is the same as that of the recess D illustrated in FIG. 5, except that the former is upside down. The recess D is configured with a tapered surface similar to that in the case of FIG. 5. The angle of the tapered surface may be set to an angle at which a normal line on the tapered surface intersects the second electrode plate 35. Therefore, the second electrode plate 35 is located on a normal line with respect to the surface (the tapered surface) of the recess D in the auxiliary electrode AUX. More preferably, the angle of the tapered surface is an angle at which the intersections between the plurality of normal lines with respect to the top surface of the auxiliary electrode AUX and the bottom surface of the second electrode plate 35 exist in the central region of the second electrode plate 35 in the ring width direction. The central region in the ring width direction is a region located between the outer peripheral region and the inner peripheral region of the annular second electrode plate 35. As a result, the same effect as in the case of FIG. 5 can be obtained.

The recess D may be provided in both the auxiliary electrode AUX and the second electrode plate 35.

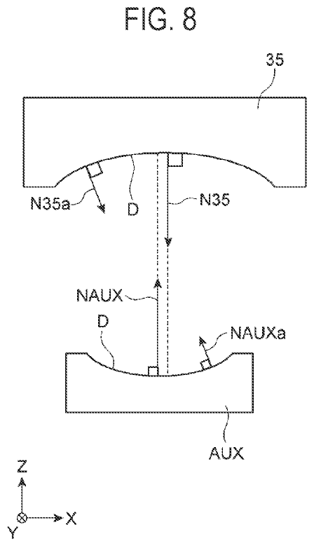

FIG. 8 is a view illustrating an example of a positional relationship between the auxiliary electrode AUX and the second electrode plate 35.

In this example, both the auxiliary electrode AUX and the second electrode plate 25 have a recess D. The recess D in the second electrode plate 35 is located on a normal line NAUX with respect to the surface of the recess D in the auxiliary electrode AUX. In addition, the recess D in the auxiliary electrode AUX is located on a normal line N35 with respect to the surface of the recess D in the second electrode plate 35.

A plurality of normal lines NAUX and NAUXa may be set for the surface of the recess D in the auxiliary electrode AUX. The central normal line NAUX is the normal line at the deepest portion of the recess D in the auxiliary electrode AUX. The normal line NAUX extends toward the deepest portion of the recess D in the second electrode plate 35.

A plurality of normal lines N35 and N35a may also be set on the surface of the recess D in the second electrode plate 35. The central normal line N35 is the normal line at the deepest portion of the recess D in the second electrode plate 35. The normal line N35 extends toward the deepest portion of the recess D in the auxiliary electrode AUX.

When an XYZ three-dimensional Cartesian coordinate system is set, the horizontal plane is indicated by the XY plane. In the case of this example, the vertical cross section passing through the vertical central axis of the substrate placement region is given as the XZ plane. Assuming that the central axis is the Z axis, the shape of the recess D in the auxiliary electrode AUX viewed from the Z-axis direction is an annulus centered on the Z axis. The shape of the recess D in the second electrode plate 35 viewed from the Z-axis direction is also an annulus centered on the Z-axis.

Electrons in the vicinity of the surface of the recess D in the auxiliary electrode AUX are accelerated toward the recess D in the second electrode plate 35 in the XZ plane. The accelerated electrons are concentrated toward the second electrode plate 35. In contrast, electrons in the vicinity of the surface of the recess D in the second electrode plate 35 are accelerated toward the recess D in the auxiliary electrode AUX in the XZ plane. The accelerated electrons are concentrated toward the auxiliary electrode AUX. Therefore, the plasma density in the substrate peripheral region increases. As a result, it is possible to suppress the increase of plasma density in the central portion of the substrate placement region. Therefore, it is possible to improve the in-plane uniformity of plasma.

Next, power supply to the auxiliary electrode will be described.

In the above, an example of supplying radio-frequency power to the auxiliary electrode AUX via the edge ring ER or the stage 16 has been described. However, the wiring may be connected to the auxiliary electrode AUX to be directly connected to a radio-frequency power supply. In addition, an electrode may be provided inside a dielectric material under the auxiliary electrode AUX, and the electrode and the radio-frequency power supply may be connected via a wire. Radio-frequency power may be supplied to the auxiliary electrode AUX by capacitively coupling the electrode inside the dielectric material below the auxiliary electrode AUX to the auxiliary electrode AUX. The power supply connected to the auxiliary electrode AUX may be a power supply SA and/or a power supply SF, or may be a radio-frequency power supply, a pulse power supply, or a DC power supply different from the power supply SA and the power supply SF.

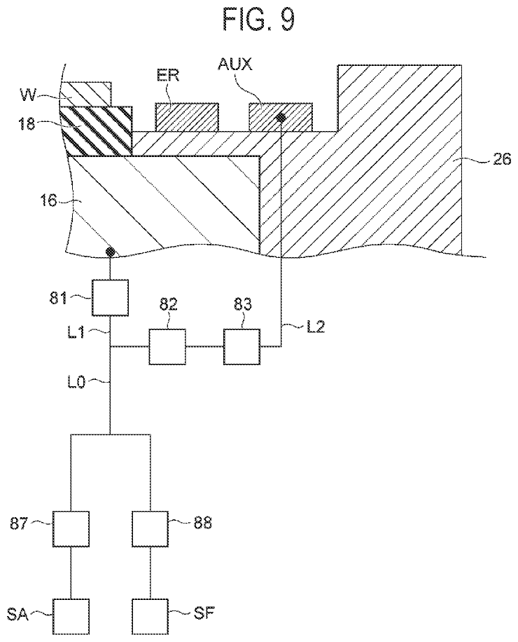

FIG. 9 is a view illustrating a vertical cross-sectional configuration around a substrate in the plasma processing apparatus according to the exemplary embodiment. This example illustrates an example in which a plurality of power supplies and an auxiliary electrode AUX are connected via wires.

The power supply SA is connected to the stage 16 via a first matcher 87, a common wire L0, and a first branch wire L1. The power supply SA is connected to the auxiliary electrode AUX via the first matcher 87, the common wire L0, and a second branch wire L2. The common wire L0 is branched into the first branch wire L1 and the second branch wire L2, and the second branch wire L2 is connected to the auxiliary electrode AUX without going through the stage 16. The power supply SA of this example is a radio-frequency power supply for plasma generation.

The power supply SF is connected to the stage 16 via a second matcher 88, the common wire L0, and the first branch wire L1. The power supply SF is connected to the auxiliary electrode AUX via the second matcher 88, the common wire L0, and the second branch wire L2. The power supply SF of this example is a radio-frequency power supply for ion attraction.

A first variable impedance circuit 81 and/or a second variable impedance circuit 82 is provided on the first branch wire L1 and/or on the second branch wire L2. Each variable impedance circuit may be a circuit having any configuration as long as the circuit has a variable impedance. In an example, the first variable impedance circuit 81 and/or the second variable impedance circuit 82 may include a variable capacitance capacitor.

A sensor 83 configured to measure a self-bias voltage or a voltage waveform generated in the auxiliary electrode AUX may be provided between the auxiliary electrode AUX and the second variable impedance circuit 82. The controller 95 may also obtain a peak-to-peak voltage (Vpp) from this voltage waveform. In this case, the magnitude of the self-bias voltage or the peak-to-peak voltage acquired by the sensor 83 may be fed back to the controller 95 illustrated in FIG. 1. The controller 95 illustrated in FIG. 1 may control the power supply SA, the power supply SF, the power supply SB, the first variable impedance circuit 81, and/or the second variable impedance circuit 82.

The controller 95 illustrated in FIG. 1 controls the outputs of these power supplies and controls the impedances of the variable impedance circuits. For example, when the plasma density in the substrate peripheral region is lower than a reference value, the controller 95 performs control that increases the plasma density. For example, the controller 95 reduces the impedance of the second variable impedance circuit 82 such that the amount of power flowing through the second branch wire L2 increases. As illustrated in FIG. 3, the controller 95 increases the magnitude (absolute value) of the negative bias voltage (−V2) output from the power supply SB (FIG. 1). Through this feedback control, it is possible to increase the plasma density in the substrate peripheral region. In addition, when the plasma density in the substrate peripheral region is equal to or higher than the reference value, the controller 95 performs control that reduces the plasma density by a method opposite to the above-mentioned method.

In the plasma processing apparatus of this example, first radio-frequency power and second radio-frequency power are supplied from the power supply SA and the power supply SF to the auxiliary electrode AUX via the second variable impedance circuit 82. Therefore, it is possible to adjust the radio-frequency power supplied to the central portion and the peripheral portion of the stage 16, and thus it is possible to actively control the potential of the auxiliary electrode AUX. Therefore, it is possible to perform control to make the in-plane uniformity of plasma higher.

An electrode may be provided inside a dielectric material under the auxiliary electrode AUX, and various exemplified power supplies may be connected to the electrode instead of the auxiliary electrode AUX.

The plasma processing apparatus of this example includes a power transmission path (the third feeding line) passing through the first branch wire L1 and a power transmission path (the fourth feeding line) passing through the second branch wire L2. The third feeding line supplies a periodic signal output from the power supply SA (the first power supply) to the stage 16 (the first lower electrode). The fourth feeding line supplies the periodic signal output from the power supply SA (the first power supply) to the auxiliary electrode AUX (the second lower electrode). The plasma processing apparatus includes the first variable impedance circuit 81 on the first branch wire L1. The plasma processing apparatus includes the second variable impedance circuit 82 on the second branch wire L2. Even if only one of these variable impedance circuits is used, it is possible to achieve a power distribution function.

By adjusting the impedances in the first variable impedance circuit 81 and the second variable impedance circuit 82, it is possible to adjust the amount of power supplied to a target lower electrode. Therefore, it is possible to adjust the ratio of the power supplied to the stage 16 and the power supplied to the auxiliary electrode AUX. The plasma density depends on the amount of power supplied to a target electrode. Therefore, it is possible to improve the in-plane uniformity of plasma by adjusting the ratio of the amounts of supplied power.

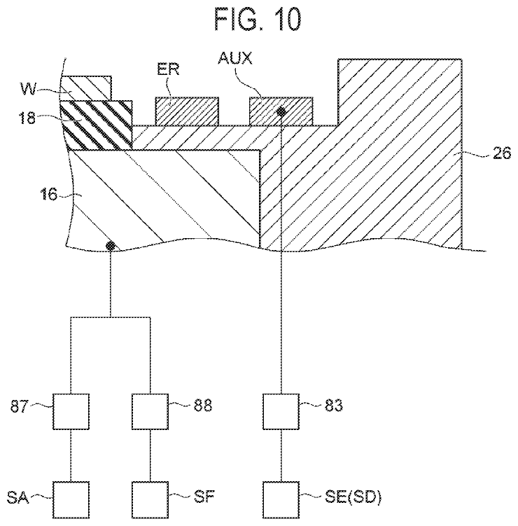

FIG. 10 is a view illustrating a vertical cross-sectional configuration around a substrate in the plasma processing apparatus according to the exemplary embodiment.

The power supply SA is connected to the stage 16 via the first matcher 87. The power supply SA of this example is a radio-frequency power supply for plasma generation. The first radio-frequency power is supplied to the stage 16 from the power supply SA.

The power supply SF is connected to the stage 16 via the second matcher 88. The power supply SF in this example is a radio-frequency power supply for ion attraction. The second radio-frequency power is supplied to the stage 16 from the power supply SF.

The power supply SE is connected to the auxiliary electrode AUX via the sensor 83. The power supply SE controls the potential of the auxiliary electrode AUX. By adjusting the potential of the auxiliary electrode AUX, it is possible to control the plasma density in the substrate peripheral region. In addition, by adjusting the output of the power supply SA for plasma generation, it is possible to adjust the plasma density in the substrate placement region. The power supply SE is a power supply different from the power supply SA and the power supply SF, and may be a radio-frequency power supply. In addition, the power supply SE may be a pulse power supply.

The plasma processing apparatus of this example includes the power supply SE (the fifth power supply) configured to supply a periodic signal to the auxiliary electrode AUX. When the periodic signal is applied to the auxiliary electrode AUX, it is possible to improve the density of plasma generated in the vicinity of the auxiliary electrode AUX.

The plasma processing apparatus of this example further includes the sensor 83 configured to measure a self-bias voltage or a voltage waveform generated in the auxiliary electrode AUX. The controller 95 illustrated in FIG. 1 may control the output of the power supply SB (the second power supply) according to the measurement value measured by the sensor 83. The measurement value measured by the sensor 83 correlates with the amount of electrons reflected by the auxiliary electrode AUX, that is, the plasma density in the substrate peripheral region. In addition, as described above, it is possible to adjust the plasma density by adjusting the output of the power supply SB. Therefore, the controller 95 adjusts the output of the power supply SB according to the plasma density corresponding to the measurement value. For example, when the plasma density corresponding to the measurement value of the sensor 83 is lower than the reference value, the controller 95 increases the output of the power supply SB (the magnitude of the negative bias voltage). Further, when the plasma density corresponding to the measurement value of the sensor 83 is equal to or higher than the reference value, the controller 95 decreases the output of the power supply SB (the magnitude of the negative bias voltage). By this feedback control, it is possible to control the plasma density in the substrate peripheral region to approach the reference value. Therefore, it is possible to improve the in-plane uniformity of plasma.

The plasma processing apparatus of this example includes the sensor 83 configured to measure a self-bias voltage or a voltage waveform generated in the auxiliary electrode AUX. The controller 95 may control the output of the power supply SE (the fifth power supply) according to the measurement value measured by the sensor 83. The measurement value measured by the sensor 83 correlates with the amount of electrons reflected by the auxiliary electrode AUX, that is, the plasma density in the substrate peripheral region. The controller 95 is able to control the plasma density in the substrate peripheral region by adjusting the output of the power supply SE according to the plasma density corresponding to the measurement value. For example, when the plasma density corresponding to the measurement value of the sensor 83 is lower than the reference value, the controller 95 increases the output of the power supply SE (the magnitude of the amplitude center voltage of the negative bias voltage and/or the power). When the plasma density corresponding to the measurement value of the sensor 83 is equal to or higher than the reference value, the controller 95 decreases the output of the power supply SE (the magnitude of the amplitude center voltage of the negative bias voltage and/or the power). This makes it possible to control the plasma density in the substrate peripheral region to approach the reference value. By this feedback control, it is possible to improve the in-plane uniformity of plasma. The reference value and the correlation between the measurement value and the plasma density may be stored in advance in the storage part 97 of FIG. 1.

In addition, instead of the power supply SE (the fifth power supply), the power supply SD (the fourth power supply) configured to generate a DC voltage may be used. In addition to the power supply SE, the power supply SD configured to generate a DC voltage may be connected to the auxiliary electrode AUX. That is, the plasma processing apparatus of this example may include the power supply SD (the fourth power supply) configured to supply a DC voltage to the auxiliary electrode AUX (the second lower electrode).

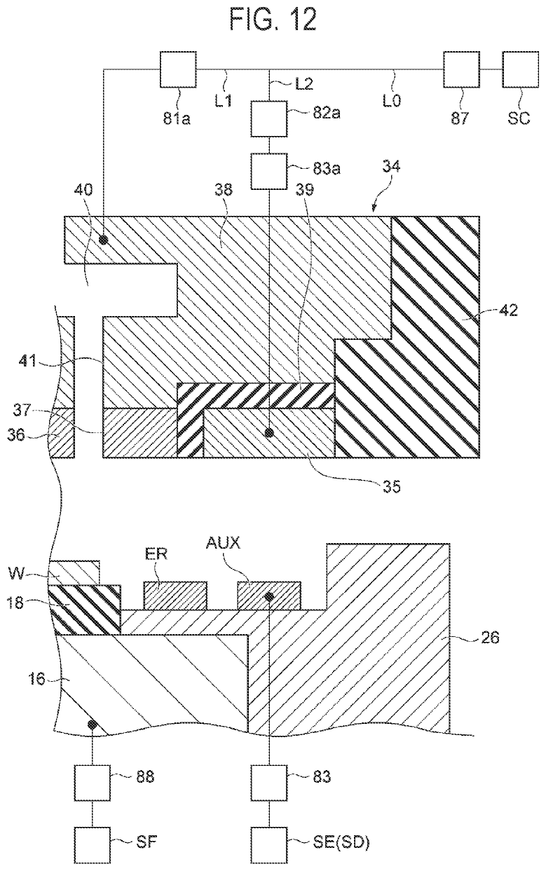

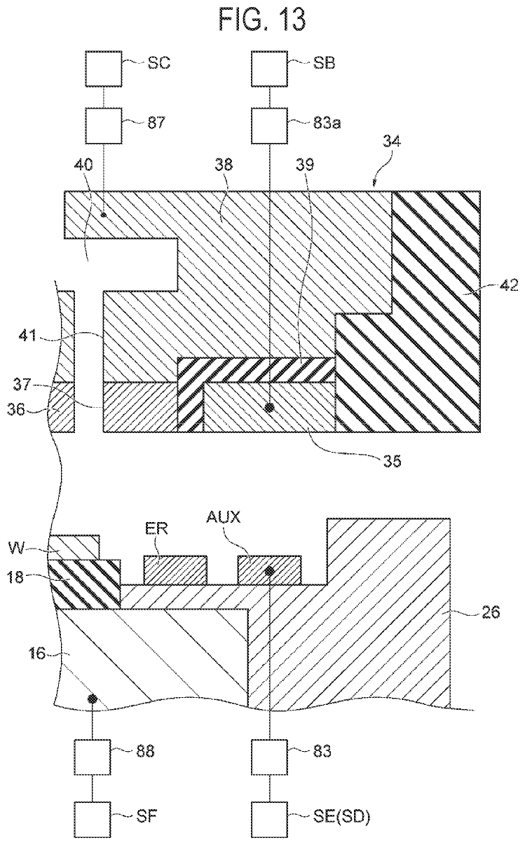

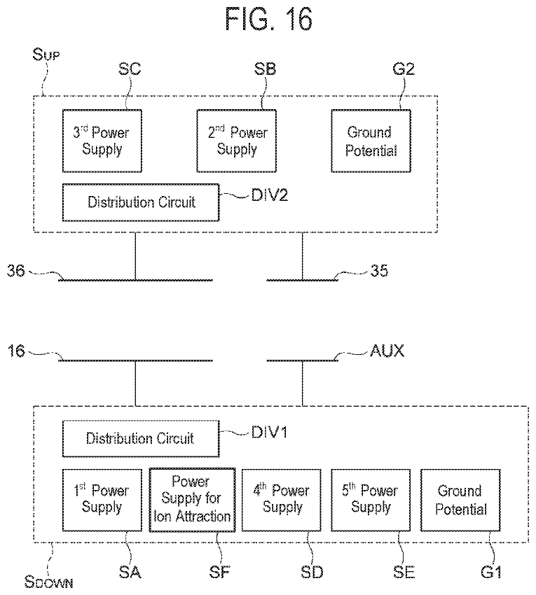

In addition, instead of or in addition to the power supply SA which is connected to the stage 16 and generates the first radio-frequency power (a periodic signal), the power supply SC (the third power supply) illustrated in FIG. 12 or FIG. 16 may be connected to the second electrode plate 35. In this case, the output from the power supply SC may be branched as illustrated in FIG. 12.

When a DC voltage is supplied to the auxiliary electrode AUX, it is possible to apply a force to electrons directed to the auxiliary electrode AUX, and thus it is possible to control the plasma density in the vicinity of the auxiliary electrode AUX. For example, when the plasma density corresponding to the measurement value of the sensor 83 is lower than the reference value, the controller 95 increases the output of the power supply SD (the magnitude of the negative bias voltage). As a result, it is possible to apply a repulsive force to the electrons, and the electrons move away from the auxiliary electrode AUX (toward plasma). Since these electrons contribute to plasma generation, the plasma density in the substrate peripheral region increases to approach the reference value. In contrast, when the plasma density corresponding to the measurement value of the sensor 83 is equal to or higher than the reference value, the controller 95 decreases the output of the power supply SD (the magnitude of the negative bias voltage). In this way, the controller 95 illustrated in FIG. 1 is able to improve the in-plane uniformity of plasma density by controlling the plasma density in the substrate peripheral region.

The plasma processing apparatus in this example uses the power supply SE (SD) different from the power supply SA and the power supply SF to supply radio-frequency power to the auxiliary electrode AUX. Therefore, since it is possible to adjust the radio-frequency power supplied from the power supply SE (SD) to the substrate peripheral region independently of the power supply SA and the power supply SF that generate plasma in the central portion of the stage 16, it is possible to actively control the potential of the auxiliary electrode AUX. Therefore, it is possible to perform control to make the in-plane uniformity of plasma higher.

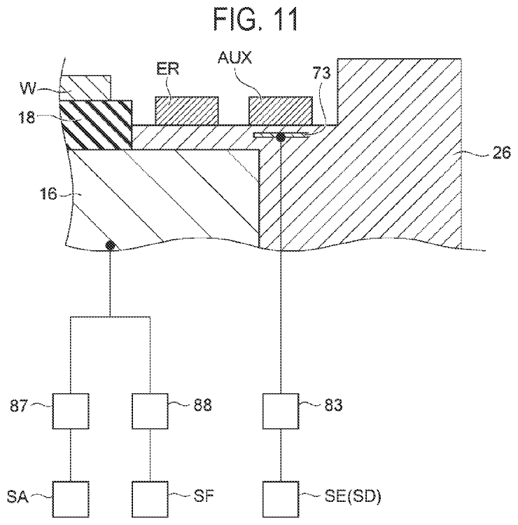

FIG. 11 is a view illustrating a vertical cross-sectional configuration around a substrate in the plasma processing apparatus according to the exemplary embodiment. As illustrated in this example, an electrode 73 for power supply may be provided inside the insulating member 26 located below the auxiliary electrode AUX. In the plasma processing apparatus illustrated in FIG. 11, instead of the auxiliary electrode AUX in FIG. 10, the power supply SE (SD) is connected to the power supply electrode 73 via the sensor 83. The configuration of FIG. 11 is the same as that illustrated in FIG. 10 except that the potential applied to the auxiliary electrode AUX is controlled via the electrode 73, and exhibits the same function and effect.

That is, the electrode 73 is connected to the power supply SE (SD). The sensor 83 configured to measure a self-bias voltage or a voltage waveform generated in the auxiliary electrode AUX may be provided between the electrode 73 and the power supply SE (SD). The sensor 83 may be directly connected to the auxiliary electrode AUX. The self-bias voltage or the voltage waveform (or the magnitude of the peak-to-peak voltage) acquired by the sensor 83 may be fed back to the controller 95 (FIG. 1) to control the plasma density as in the case of FIG. 10. The output of the power supply SE (SD) or the power supply SB (FIG. 1) may be controlled by the controller 95.

The plasma processing apparatus in this example uses the power supply SE (SD) different from the power supply SA and the power supply SF to supply radio-frequency power to the auxiliary electrode AUX. Therefore, since it is possible to adjust the radio-frequency power supplied from the power supply SE (SD) to the substrate peripheral region independently of the power supply SA and the power supply SF that generate plasma in the central portion of the stage 16, it is possible to actively control the potential of the auxiliary electrode AUX. Therefore, it is possible to perform control to make the in-plane uniformity of plasma higher.

Various types may be considered as the connection relationship between the auxiliary electrode AUX and the power supply. For example, the power supply SE configured to generate radio-frequency power is connected to the electrode 73. Instead of the power supply SE configured to generate radio-frequency power, the power supply SD configured to generate a DC voltage is connected to the electrode 73. A connection, such as connecting the power supply SD configured to generate a DC voltage to the auxiliary electrode AUX in the state in which the power supply SE configured to generate a radio-frequency voltage is connected to the electrode 73, is also conceivable.

The power supply SD may be a DC power supply. The potential of the auxiliary electrode AUX (the voltage between the auxiliary electrode AUX and the ground potential) fluctuates periodically with reference to the self-bias voltage Vdc (an amplitude center voltage) illustrated in FIG. 3. Therefore, the average potential value of the auxiliary electrode AUX is Vdc. The potential of the auxiliary electrode AUX may be fluctuated by directly connecting an AC power supply to the auxiliary electrode AUX. In addition, the potential of the auxiliary electrode AUX may be fluctuated by being coupled with the AC potential applied to the stage 16. Here, when a negative DC voltage Va is applied to the electrode 73 by the power supply SD, the average potential value of the auxiliary electrode AUX becomes the sum of Vdc and Va. That is, by connecting the power supply SD, which is a DC power supply, to the electrode 73 or the auxiliary electrode AUX, it is possible to correct the entire potential of the auxiliary electrode AUX that fluctuates periodically.

It is also possible to configure both the power supply SE and the power supply SD as radio-frequency power supplies. In this case, first radio-frequency power and second radio-frequency power are applied to the auxiliary electrode AUX or the electrode 73.

In the above, an example in which a DC voltage is applied to the second electrode plate 35 from the power supply SB has been described. Instead of the power supply SB configured to generate a DC voltage, a power supply SC configured to generate an AC voltage may be connected to the second electrode plate 35. Next, a case in which radio-frequency power is applied to the second electrode plate 35 will be described.

FIG. 12 is a view illustrating a vertical cross-sectional configuration around a substrate in the plasma processing apparatus according to the exemplary embodiment. In the plasma processing apparatus of this example, the power supply SA for plasma generation illustrated in FIG. 11 is removed from the stage 16, and instead, the power supply SC is connected to the second electrode plate 35 and the electrode support 38 (the first electrode plate 36). In other words, in this example, the power supply for plasma generation is connected to the upper electrode, rather than to the lower electrode. A power supply for plasma generation may be connected to the upper electrode in addition to the lower electrode.

The power supply SC is connected to the electrode support 38 (the first electrode plate 36) via the first matcher 87, the common wire L0, and the first branch wire L1. The power supply SC of this example is a radio-frequency power supply for plasma generation, and the first radio-frequency power is supplied to the electrode support 38 and the first electrode plate 36 via the first branch wire L1 from the power supply SC.

In addition, the power supply SC is connected to the second electrode plate 35 via the first matcher 87, the common wire L0, and the second branch wire L2. The common wire L0 is branched into the first branch wire L1 and the second branch wire L2, and the second branch wire L2 is connected to the second electrode plate 35 without going through the electrode support 38. From the power supply SC of this example, the first radio-frequency power is supplied to the second electrode plate 35 via the second branch wire L2.

The power supply SF is connected to the stage 16 via the second matcher 8. The power supply SF in this example is a radio-frequency power supply for ion attraction.

The power supply SE is connected to the auxiliary electrode AXU via the sensor 83. Although the power supply SE in this example is an AC power supply, a power supply SD, which is a DC power supply, may be used instead of the power supply SE. Either one or both of the power supply SE and the power supply SD may be connected to the auxiliary electrode AUX. The effects obtained by using the power supply SE (SD) are as described above.

Since radio-frequency power is supplied to the second electrode plate 35, a self-bias voltage, which is a negative DC voltage, is generated. Therefore, the magnitude (absolute value) of the self-bias voltage generated in the second electrode plate 35 is set to be the same as the magnitude (absolute value) of the self-bias voltage generated in the auxiliary electrode AUX. Alternatively, the magnitude (absolute value) of the self-bias voltage generated in the second electrode plate 35 may be set to be equal to or greater than the magnitude (absolute value) of the self-bias voltage generated in the auxiliary electrode AUX. This makes it possible to efficiently return accelerated electrons, which have not collided with the particles in the plasma, into the plasma again.

A first variable impedance circuit 81a and/or a second variable impedance circuit 82a are provided on the first branch wire L1 and/or on the second branch wire L2. Each variable impedance circuit may be a circuit having any configuration as long as the circuit has a variable impedance. In an example, the first variable impedance circuit 81a and/or the second variable impedance circuit 82a may include a variable capacitance capacitor.

A sensor 83a configured to measure a self-bias voltage or a voltage waveform generated in the second electrode plate 35 may be provided between the second electrode plate 35 and the second variable impedance circuit 82a. In this case, the self-bias voltage or the voltage waveform (or the magnitude of the peak-to-peak voltage) acquired by the sensor 83a may be fed back to the controller 95 illustrated in FIG. 1 to perform the same feedback control as described above. The controller 95 illustrated in FIG. 1 may set the plasma density in the substrate peripheral region to a target reference value by controlling the power supply SC, the power supply SF, the power supply SE (SD), the first variable impedance circuit 81a, and/or the second variable impedance circuit 82a.

The plasma processing apparatus of this example includes a power supply SC (the third power supply) configured to supply a periodic signal to the second electrode plate 35. When the periodic signal is applied to the second electrode plate 35, it is possible to improve the density of plasma generated in the vicinity of the second electrode plate 35. In FIG. 12, the power supply SF (the first power supply) configured to supply a periodic signal to the stage 16 (the first lower electrode) is a power supply for ion attraction.

The plasma processing apparatus of this example includes a power transmission path (the first feeding line) passing through the first branch wire L1 and a power transmission path (the second feeding line) passing through the second branch wire L2. The first feeding line supplies the periodic signal output from the power supply SC (the third power supply) to the first electrode plate 36 (the first upper electrode) via the electrode support 38. The second feeding line supplies the periodic signal output from the power supply SC to the second electrode plate 35 (the second upper electrode). A first variable impedance circuit 81a or a second variable impedance circuit 82a is provided on the first branch wire L1 (the first feeding line) or the second branch wire L2 (the second feeding line).

By adjusting the impedance in the first variable impedance circuit 81a and/or the second variable impedance circuit 82a, it is possible to adjust the amount of power supplied to a target upper electrode. Therefore, it is possible to adjust the ratio of the power supplied to the first electrode plate 36 and the power supplied to the second electrode plate 35. The plasma density depends on the amount of power supplied to the target electrode. Therefore, it is possible to improve the in-plane uniformity of plasma by adjusting the ratio of the amounts of supplied power.

In this example as well, the power supply SA may be connected to the stage 16 as in the examples illustrated in FIGS. 9 to 11.

As described above, the plasma processing apparatus of FIG. 12 includes a sensor 83 configured to measure a self-bias voltage or a voltage waveform generated in the auxiliary electrode AUX, and a sensor 83a configured to measure a self-bias voltage or a voltage waveform generated in the second electrode plate 35. With only one of these sensors 83 and 83a, it is possible to perform a feedback control based on a sensor output. The controller 95 illustrated in FIG. 1 controls the impedance of the first variable impedance circuit 81a and the impedance of the second variable impedance circuit 82a according to measurement values measured by the sensors 83 and 83a. These measurement values are self-bias voltages or voltage waveforms (or magnitudes of peak-to-peak voltages). As illustrated in FIG. 9, radio-frequency power may be applied to the lower auxiliary electrode AUX from the power supply SA and the power supply SF via the variable impedance circuits. In this case, the controller 95 illustrated in FIG. 1 includes the sensor 83 configured to measure a self-bias voltage generated in the auxiliary electrode AUX (the second lower electrode) and controls the impedances of the variable impedance circuits 81 and 82 illustrated in FIG. 9 according to a measurement value measured by the sensor 83.

The amount of power that can be transmitted changes according to impedance values. There is a correlation between the plasma density in the substrate peripheral region and the measurement value. When it is determined that the plasma density in the substrate peripheral region is lower than the reference value based on the measurement value, the controller 95 performs control to increase the plasma density. When it is determined that the plasma density in the substrate peripheral region is equal to or higher than the reference value, the controller 95 performs control to decrease the plasma density. The reference value and the correlation between the measurement value and the plasma density may be stored in advance in the storage part 97 of FIG. 1.

The method of increasing the plasma density in the substrate peripheral region is as described above. The impedance of a variable impedance circuit controls the plasma density generated in the space on the substrate placement region (the space between the stage 16 and the first electrode plate 36) and the space on the substrate peripheral region (the space between the auxiliary electrode AUX and the second electrode plate 35). The measurement value measured by the sensor correlates with the plasma density in the substrate peripheral region. Therefore, the controller 95 is capable of adjusting the amount of power to be supplied to the electrodes connected to the variable impedance circuits 81a and 82a by adjusting impedances of the variable impedance circuits 81a and 82a according to the plasma density corresponding to the measurement value. The plasma density depends on the amount of power supplied to a target electrode. Therefore, it is possible to improve the in-plane uniformity of plasma by adjusting the ratio of the amounts of supplied power based on the measurement values measured by the sensor 83 and 83a.

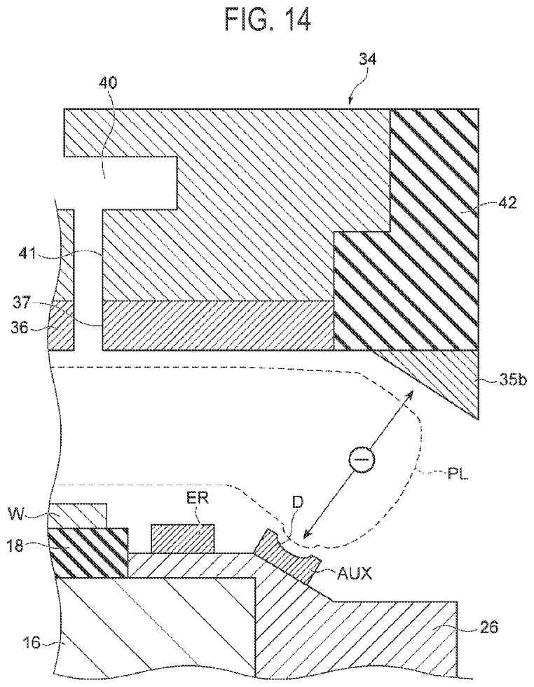

FIG. 13 is a view illustrating a vertical cross-sectional configuration around a substrate in the plasma processing apparatus according to the exemplary embodiment. This example is the same in configuration as the plasma processing apparatus illustrated in FIG. 12, except for the connection relationship of upper power supplies.

The power supply SC is connected to the electrode support 38 (the first electrode plate 36) via the first matcher 87. The power supply SB is connected to the second electrode plate 35 via the sensor 83a. The power supply SC is a radio-frequency power supply for plasma generation illustrated in FIG. 12. As the configuration of the upper power supply SB, the same configuration as that of the lower power supply SE (SD) may be adopted. In other words, the power supply SB is a DC power supply configured to generate a DC voltage, but may be a pulse power supply or a radio-frequency power supply. In addition to the power supply SB (DC voltage), another power supply (a pulse power supply or a radio-frequency power supply) may be connected to the second electrode plate 35.

In any case, as illustrated in FIG. 3, Condition 1 in which the magnitude of the average value (or effective value) of the potential of the second electrode plate 35 is equal to or greater than the magnitude of the average value (or effective value) of the potential of the auxiliary electrode AUX (Condition 1) is satisfied. The outputs of the power supply SB and the power supply SE (SD) are set to satisfy Condition 1. In order to satisfy Condition 1, the power supply SC and the power supply SF may be controlled in addition to the outputs of the power supply SB and the power supply SE (SD). That is, in order to satisfy Condition 1, it is possible to control outputs of at least one of the power supply SB, the power supply SE (SD), the power supply SC, and the power supply SF. When the power supply is a radio-frequency power supply (an AC power supply), the above-mentioned variable impedance circuit may be provided between the power supply and the electrode. The impedances of the variable impedance circuits may be controlled to satisfy Condition 1. This control may be performed based on the values of self-bias voltages or voltage waveforms (or the magnitudes of peak-to-peak voltages) generated in the second electrode plate 35 and/or the auxiliary electrode AUX and acquired by the sensors 83 and 83a. The feedback control method is the same as the above-mentioned control.

This makes it possible to return the accelerated electrons that have not collided with the particles in plasma into the plasma again. Thus, it is possible to efficiently generate plasma even in the substrate peripheral portion in which plasma density is low. Therefore, it is possible to improve the uniformity of plasma.

The second electrode plate 35 and the auxiliary electrode AUX described above may face each other in the substrate peripheral portion, and it is not necessary to dispose the second electrode plate 35 and the auxiliary electrode AUX parallel with the substrate placement region. In addition, it is not necessary to connect a DC power supply or a radio-frequency power supply to the second electrode plate 35 and the auxiliary electrode AUX.

FIG. 14 is a view illustrating a vertical cross-sectional configuration around a substrate in the plasma processing apparatus.

As illustrated in the figure, the insulating member 26 has an inclined surface, and the auxiliary electrode AUX is placed on the inclined surface. The auxiliary electrode AUX is electrically connected to the chamber 10 via a wire and is grounded. The shape of the auxiliary electrode AUX is the same as that illustrated in FIG. 6, but the shape is not limited thereto. As the shape of the recess D, the recess illustrated in FIG. 7 may also be used, and the auxiliary electrode AUX may be flattened without being provided with the recess D. A second electrode plate 35b having a flat surface inclined from the horizontal direction is provided to face the auxiliary electrode AUX. That is, the second electrode plate 35b is located on a normal line with respect to the surface of the recess D in the auxiliary electrode AUX. The second electrode plate 35b is grounded via the sidewall of the chamber 10. The second electrode plate 35b may be configured with the sidewall of the chamber 10 or may be configured with a deposition shield. As in the second electrode plate 35 illustrated in FIG. 4 or FIG. 5, a recess D may be provided not in the auxiliary electrode AUX, but in the second electrode plate 35b. Both the auxiliary electrode AUX and the second electrode plate 35b may be provided with a recess D.

In FIG. 14, the insulating member 39 illustrated in FIG. 13 does not exist, and the horizontal end portion of the first electrode plate 36 is in contact with the inner peripheral surface of the insulative shielding member 42. The first electrode plate 36 and the second electrode plate 35b are electrically separated from each other by the insulative shielding member 42.

In the plasma processing apparatus of the present embodiment, the auxiliary electrode AUX having the recess D is placed on an inclined surface, and the second electrode plate 35b has a flat surface inclined from the horizontal direction and faces the auxiliary electrode AUX. That is, a normal line with respect to the bottom surface of the recess D of the auxiliary electrode AUX is disposed to be inclined with respect to a normal line with respect to the substrate placement region.

In the plasma processing apparatus of the present embodiment, the second electrode plate 35b and the auxiliary electrode AUX are grounded and have the same potential. The plasma PL generated between the stage 16 and the first electrode plate 36 diffuses into the space between the auxiliary electrode AUX and the second electrode plate 35b. The strength of a sheath electric field is proportional to the difference between a plasma potential and a wall potential. In addition, the plasma potential increases as the bias power increases, and becomes maximum when the phase thereof is positive. Therefore, a large potential gradient is generated between the potential of the grounded auxiliary electrode AUX and the plasma, and the electrons existing in the plasma in the vicinity of the auxiliary electrode AUX when the sheath is thin are accelerated toward the second electrode plate 35b (toward the plasma) facing the auxiliary electrode AUX. Some of the accelerated electrons collide with the particles in the plasma and contribute to the improvement of plasma density. Meanwhile, the remaining accelerated electrons that have not collided with the particles in the plasma receive a repulsive force by the sheath electric field between the second electrode plate 35b and the plasma, and are returned into the plasma. Similarly, the electrons existing in the plasma in the vicinity of the second electrode plate 35b when the sheath is thin are also accelerated toward the plasma, receive a repulsive force by the sheath electric field between the auxiliary electrode AUX and the plasma, and are returned into the plasma. Therefore, the reciprocation of accelerated electrons occurs in the space between the second electrode plate 35b and the auxiliary electrode AUX so that the plasma density in the substrate peripheral portion can be improved. Therefore, it is possible to improve the uniformity of plasma.

A radio-frequency power supply and/or a DC power supply may be electrically connected to the auxiliary electrode AUX and the second electrode plate 35b to apply a potential to the auxiliary electrode AUX and the second electrode plate 35b.

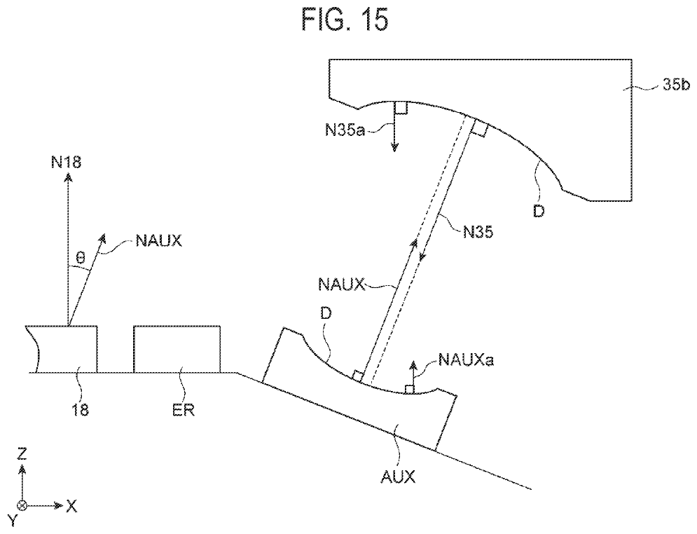

FIG. 15 is a view illustrating an example of a positional relationship between the auxiliary electrode AUX and the second electrode plate 35b.

Both the auxiliary electrode AUX and the second electrode plate 35b have a recess D. A plurality of normal lines NAUX and NAUXa may be set with respect to the surface of the recess D in the auxiliary electrode AUX. The normal line NAUX extends toward the deepest portion of the recess D in the second electrode plate 35b. The normal line NAUX at the deepest portion of the recess D in the auxiliary electrode AUX is inclined with respect to the vertical direction (the Z-axis direction).

A plurality of normal lines N35 and N35a may also be set with respect to the surface of the recess D in the second electrode plate 35b. The normal line N35 is the normal line at the deepest portion of the recess D in the second electrode plate 35. The normal line N35 extends toward the deepest portion of the recess D in the auxiliary electrode AUX. The normal line N35 at the deepest portion of the recess D of the second electrode plate 35b is also inclined with respect to the vertical direction (the Z-axis direction). The shape of each recess D is the same as that described with reference to FIG. 8, except that the recess D is inclined.

The normal line N18 on the surface of the substrate placement region on the electrostatic chuck 18 is parallel to the vertical direction (the Z-axis direction). The second electrode plate 35b and the auxiliary electrode AUX are disposed such that the normal line NAUX (or N35) with respect to the bottom surface of the recess D is inclined by an angle θ relative to the normal line N18 with respect to the substrate placement region. By changing the distance between the second electrode plate 35b and the auxiliary electrode AUX and the inclination angle θ, it is possible to change the intensity and shape of the plasma in the substrate peripheral region. Since the degree of freedom in designing the in-plane distribution of plasma density is improved, it is possible to improve the in-plane uniformity of plasma.

Electrons in the vicinity of the surface of the recess D in the auxiliary electrode AUX are accelerated toward the recess D in the second electrode plate 35b in the XZ plane. The accelerated electrons are concentrated toward the second electrode plate 35b. In contrast, electrons in the vicinity of the surface of the recess D in the second electrode plate 35b are accelerated toward the recess D in the auxiliary electrode AUX in the XZ plane. The accelerated electrons are concentrated toward the auxiliary electrode AUX. Therefore, the plasma density in the substrate peripheral region increases. As a result, it is possible to suppress the increase of plasma density in the central portion of the substrate placement region. Therefore, it is possible to improve the in-plane uniformity of plasma.

The second electrode plate 35b may be configured with the inner wall of the chamber 10 (the processing container) or the deposition shield provided along the inner wall of the chamber 10. The inner wall surface of the chamber 10 illustrated in FIG. 1 corresponds to these elements. In this case, since the second electrode plate 35 also serves as the inner wall of the chamber or the deposition shield, the number of components can be reduced while achieving the above-mentioned effects. The structures of FIGS. 14 and 15 are also applicable to other embodiments.

FIG. 16 is a view illustrating a connection relationship between power supplies and electrodes. Various electrical connections of the above-mentioned electrodes and power supplies may be made.

For example, in the above-described embodiments, the second electrode plate 35 (35b) and the auxiliary electrode AUX may be electrically grounded. In this case, the auxiliary electrode AUX is connected to a ground potential G1, and the second electrode plate 35 is connected to aground potential G2. When a plasma sheath having a positive potential is formed between the auxiliary electrode AUX and the second electrode plate 35, electrons in the vicinity of these electrodes travel toward the sheath. The electrons that have moved toward the sheath contribute to plasma generation, and thus the plasma density in the substrate peripheral region increases. Therefore, it is possible to improve the in-plane uniformity of plasma.

As a group of electrodes below the plasma generation region, there are a stage 16 and an auxiliary electrode AUX. A power supply circuit group S_{DOWN} for the lower electrode group may be connected to this electrode group. The power supply circuit group S_{DOWN} includes a first power supply SA, a power supply SF for ion attraction, a fourth power supply SD, a fifth power supply SE, aground potential G1, and a distribution circuit DIV1 for distributing power.

As a group of electrodes above the plasma generation region, there are a first electrode plate 36 and a second electrode plate 35. A power supply circuit group Sup for the upper electrode group may be connected to this electrode group. The power supply circuit group Sup includes a third power supply SC, a second power supply SB, a ground potential G2, and a distribution circuit DIV2 for distributing power.

As illustrated in FIG. 9, the configuration of the lower distribution circuit DIV1 is a circuit including variable impedance circuits in a power transmission path, and is a circuit that changes the power supply ratio to the connected electrodes according to the value of impedances.

Power may be supplied from the lower power supply to the stage 16 and the auxiliary electrode AUX via the distribution circuit DIV1. The power may be supplied to the stage 16 and the auxiliary electrode AUX from the lower power supply without going through the distribution circuit DIV1. The first power supply SA is a radio-frequency power supply, and the power supply SF for ion attraction is a power supply having a lower frequency than the first power supply SA. The fourth power supply SD is a DC power supply, and the fifth power supply SE is a radio-frequency power supply. There are multiple combinations of these power supplies.

The power supply SF for ion attraction is connected to the stage 16 through or without going through a distribution circuit DIV1. Assuming that the power supply for plasma generation is the first power supply SA, the first power supply SA may be connected to the stage 16 through or without going through the distribution circuit DIV1. Any one of the fourth power supply SD, the fifth power supply SE, and the ground potential G1 may be connected to the auxiliary electrode AUX. Both the fourth power supply SD and the fifth power supply SE may be connected to the auxiliary electrode AUX without going through the distribution circuit DIV1. A sensor configured to measure a self-bias voltage or a voltage waveform of the auxiliary electrode AUX may be provided in the connected path. The outputs of the first power supply SA, the fourth power supply SD, and the fifth power supply SE may be connected to the stage 16 and the auxiliary electrode AUX via the distribution circuit DIV1. A sensor configured to measure a self-bias voltage or a voltage waveform may be placed in any power transmission path, and control may be performed to improve the in-plane uniformity of plasma based on the feedback method described above.

As illustrated in FIG. 12, the configuration of the upper distribution circuit DIV2 is a circuit including variable impedance circuits in a power transmission path, and is a circuit that changes the power supply ratio to the connected electrodes according to the ratio of impedances.

Power may be supplied from an upper power supply to the first electrode plate 36 and the second electrode plate 35 via the distribution circuit DIV2. Power may be supplied to the first electrode plate 36 and the second electrode plate 35 from the upper power supply without going through the distribution circuit DIV2. The third power supply SC is a radio-frequency power supply. The second power supply SB is a DC power supply, but may be a pulse power supply or a radio-frequency power supply. The second power supply SB may include a DC power supply and a radio-frequency power supply (a power supply configured to supply a periodic signal), and may be configured such that a DC voltage and an AC voltage (a radio-frequency voltage) are applied to the second electrode plate 35 from the DC power supply and the radio-frequency power supply, respectively.

Assuming that the power supply for plasma generation is the third power supply SC, the third power supply SC may be connected to the first electrode plate 36 through or without going through the distribution circuit DIV2. Any one of the third power supply SC, the second power supply SB, and the ground potential G2 may be connected to the second electrode plate 35. Both the third power supply SC and the second power supply SB may be connected to the second electrode plate 35 without going through the distribution circuit DIV2. A sensor configured to measure a self-bias voltage or a voltage waveform of the second electrode plate 35 may be provided in the connection path. The outputs of the third power supply SC and the second power supply SB may be connected to the first electrode plate 36 and the second electrode plate 35 via the distribution circuit DIV2. A sensor configured to measure a self-bias voltage or a voltage waveform may be placed in any power transmission path, and a control may be performed to improve the in-plane uniformity of plasma based on the feedback method described above. The feedback control, which improves the in-plane uniformity of plasma, is applicable to all embodiments. A feedforward control may be performed instead of the feedback control.

When any of the above-mentioned power supplies connected to the auxiliary electrode AUX is selected from the lower power supply circuit group S_{DOWN}, any of the above-mentioned power supplies connected to the second electrode plate 35 may be selected from the upper power supply circuit group Sup and combined with the power supply selected from the lower power supply circuit group S_{DOWN}. For example, the power supply SD is selected as the lower power supply to which a DC voltage is applied, and the power supply SB is selected as the upper power supply to which a DC voltage is applied. Alternatively, the power supply SD is selected as the lower power supply to which a DC voltage is applied, and the power supply SB is selected as the upper power supply to which an AC voltage (a periodic signal) is applied. In this case, the power supply SB may include a power supply to which a DC voltage is applied and a power supply to which an AC voltage is applied. When the power supply SB includes an AC power supply, the power supply SB may be connected in the same manner as the power supply SC illustrated in FIG. 12, and a variable impedance circuit may be included in the power transmission path. In any combination, as illustrated in FIG. 9, the output from the first power supply SA may be branched, and a variable impedance circuit and a sensor configured to measure a self-bias voltage or a voltage waveform may be provided. The fifth power supply SE may be connected to the auxiliary electrode AUX alone or in combination with any of the above-mentioned power supply connections.

As described above, the above-described plasma processing apparatus includes the chamber 10, the stage 16, the electrostatic chuck 18 (the first lower electrode), and then auxiliary electrode AUX (the second lower electrode). The above-mentioned plasma processing apparatus further includes the first electrode plate 36 (the first upper electrode), the second electrode plate 35 or 35b (the second upper electrode), and the first power supply SA (SF). The stage 16 and the electrostatic chuck 18 are provided inside the chamber 10 and have the substrate placement region on which the semiconductor wafer W is placed. The auxiliary electrode AUX is disposed in the substrate peripheral region. The first electrode plate 36 is disposed to face the substrate placement region. The second electrode plate 35 or 35b is disposed in a region outside the first electrode plate 36 and is disposed to face the auxiliary electrode AUX. The first power supply SA (SF) supplies a periodic signal to the stage 16. At least one of the auxiliary electrode AUX and the second electrode plate 35 or 35b has a recess D. The auxiliary electrode AUX or the second electrode plate 35 or 35b is located on a normal line with respect to the surface of the recess D.

Since electrons accelerated from the vicinity of the surface of the recess D in one of the auxiliary electrode AUX and the second electrode plate 35 or 35b toward the other are concentrated, the plasma density in the substrate peripheral region increases. Thus, it is possible to suppress the increase of plasma density in the center of the substrate placement region. Therefore, it is possible to improve the in-plane uniformity of plasma.

A structure in which only the bottom surface of the second electrode plate 35 has a recess D, a structure in which only the top surface of the auxiliary electrode AUX has a recess D, and a structure in which both the top and bottom surfaces have a recess are applicable to all embodiments. The edge ring ER and the auxiliary electrode AUX described in the above may be integrated with each other.

According to the plasma processing apparatus, it is possible to improve the in-plane uniformity of plasma.

Although various exemplary embodiments have been described above, the present disclosure is not limited to the exemplary embodiments described above, and various omissions, substitutions, and changes may be made. In addition, elements in different embodiments may be combined to form other embodiments. From the foregoing description, it should be understood that various embodiments of the present disclosure have been described herein for purposes of illustration, and that various modifications can be made without departing from the scope and spirit of the present disclosure. Accordingly, the various embodiments disclosed herein are not intended to be limiting, and the true scope and spirit of the disclosure is indicated by the appended claims.

What is claimed is:

1. A plasma processing apparatus comprising:
a chamber;
a first lower electrode provided inside the chamber and having a substrate placement region on which a substrate is placed;
a second lower electrode disposed in a region outside the substrate placement region;
a first upper electrode disposed to face the substrate placement region;
a second upper electrode disposed in a region outside the first upper electrode to face the second lower electrode; and
a first power supply configured to supply a first periodic signal to the first lower electrode,
wherein at least one of the second lower electrode and the second upper electrode includes a recess, and
the second lower electrode or the second upper electrode is located on a normal line with respect to a surface of the recess.

2. The plasma processing apparatus of claim 1, wherein both the second lower electrode and the second upper electrode include the recess,
the recess in the second upper electrode is located on the normal line with respect to the surface of the recess in the second lower electrode, and
the recess in the second lower electrode is located on the normal line with respect to the surface of the recess in the second upper electrode.

3. The plasma processing apparatus of claim 2, further comprising:
a second power supply configured to supply a DC voltage to the second upper electrode.

4. The plasma processing apparatus of claim 3, further comprising:
a third power supply configured to supply a second periodic signal to the second upper electrode.

5. The plasma processing apparatus of claim 4, further comprising:
a first feeding line configured to supply, to the first upper electrode, the second periodic signal output from the third power supply; and
a second feeding line configured to supply, to the second upper electrode, the second periodic signal output from the third power supply,
wherein the first power feeing line or the second power feeing line includes a variable impedance circuit.

6. The plasma processing apparatus of claim 5, further comprising:
a fourth power supply configured to supply a DC voltage to the second lower electrode.

7. The plasma processing apparatus of claim 6, further comprising:
a third feeding line configured to supply, to the first lower electrode, the first periodic signal output from the first power supply; and
a fourth feeding line configured to supply, to the second lower electrode, the first periodic signal output from the first power supply,
wherein the third power feeing line or the fourth power feeing line includes a variable impedance circuit.

8. The plasma processing apparatus of claim 7, further comprising:
a sensor configured to measure a self-bias voltage or a voltage waveform generated in the second lower electrode or the second upper electrode; and
a controller configured to control an impedance of the variable impedance circuit according to a measurement value measured by the sensor.

9. The plasma processing apparatus of claim 8, wherein a distance between the second upper electrode and the second lower electrode is smaller than a distance between the first upper electrode and the first lower electrode.

10. The plasma processing apparatus of claim 9, further comprising:
a conductive edge ring provided between the substrate placement region on which the substrate is placed and the second lower electrode.

11. The plasma processing apparatus of claim 10, wherein the second upper electrode and the second lower electrode are disposed such that a normal line with respect to a bottom surface of the recess is inclined relative to a normal line with respect to the substrate placement region.

12. The plasma processing apparatus of claim 11, wherein the second upper electrode is configured with an inner wall of the chamber or a deposition shield provided along the inner wall of the chamber.

13. The plasma processing apparatus of claim 3, further comprising:
a sensor configured to measure a self-bias voltage or a voltage waveform generated in the second lower electrode; and
a controller configured to control an output of the second power supply according to a measurement value measured by the sensor.

14. The plasma processing apparatus of claim 13, wherein the controller is further configured to control the output of the second power supply such that the second upper electrode generates a negative DC voltage having a magnitude equal to or greater than a magnitude of the self-bias voltage generated in the second lower electrode.

15. The plasma processing apparatus of claim 1, further comprising:
a second power supply configured to supply a DC voltage to the second upper electrode.

16. The plasma processing apparatus of claim 1, further comprising:
a third power supply configured to supply a second periodic signal to the second upper electrode.

17. The plasma processing apparatus of claim 1, further comprising:
a third feeding line configured to supply, to the first lower electrode, the first periodic signal output from the first power supply; and
a fourth feeding line configured to supply, to the second lower electrode, the first periodic signal output from the first power supply,
wherein the third power feeing line or the fourth power feeing line includes a variable impedance circuit.

18. The plasma processing apparatus of claim 1, further comprising:
a fifth power supply configured to supply a third periodic signal to the second lower electrode.

19. The plasma processing apparatus of claim 18, further comprising:
a sensor configured to measure a self-bias voltage or a voltage waveform generated in the second lower electrode; and
a controller configured to control an output of the fifth power supply according to a measurement value measured by the sensor.

20. The plasma processing apparatus of claim 1, wherein the second lower electrode and the second upper electrode are electrically grounded.
